(19) United States
(12) Patent Application Publication
(10) Pub. No.: US 2024/0044940 A1
(43) Pub. Date: Feb. 8, 2024

(54) CONTACT PROBE FOR PROBE HEADS OF ELECTRONIC DEVICES

(71) Applicant: TECHNOPROBE S.P.A., Cernusco Lombardone (LC) (IT)

(72) Inventors: Roberto CRIPPA, Cernusco Lombardone (LC) (IT); Flavio MAGGIONI, Cernusco Lombardone (LC) (IT)

(73) Assignee: TECHNOPROBE S.P.A., Cernusco Lombardone (LC) (IT)

(21) Appl. No.: 18/254,056

(22) PCT Filed: Nov. 22, 2021
(86) PCT No.: PCT/EP2021/082521

§ 371 Date: May 23, 2023

(30) Foreign Application Priority Data
Nov. 25, 2020 (IT) 102020000028364

(51) Int. Cl. G01R 1/073; G01R 1/067

(52) U.S. Cl. CPC G01R 1/07307; G01R 1/06738

(57) ABSTRACT

A contact probe is disclosed having a first contact end portion adapted to abut onto a contact pad of a device under test, a second contact end portion adapted to abut onto a contact pad of a PCB board of a testing apparatus, and a rod-shaped probe body extended between the first and second contact end portions according to a longitudinal direction. The contact probe also includes an opening that extends along the probe body and along at least one contact end portion, a first opening part defining a pair of arms in the probe body and a second opening part defining a pair of end sections in the contact end portion.

### TECHNICAL FIELD

In its more general aspect, the present invention relates to a contact probe for a probe head of electronic devices and the following description is made with reference to this field of application with the sole aim of simplifying the description thereof.

### BACKGROUND ART

As it is well known, a probe head is basically a device configured to electrically connect a plurality of contact pads of a microstructure, in particular an electronic device that is integrated on a wafer, with corresponding channels of a testing apparatus that performs the functionality testing thereof, in particular the electric one, or generically the test.

The test, which is performed on integrated devices, is particularly useful for detecting and isolating defective devices as early as in the production phase. Usually, probe heads are therefore used for electrically testing devices integrated on a wafer before cutting and assembling them inside a chip containment package.

A probe head usually comprises a high number of contact elements or contact probes formed by wires of special alloys with good electric and mechanical properties and provided with at least one contact portion for a corresponding plurality of contact pads of a device under test.

A probe head of the type commonly called “vertical probe head” comprises a plurality of contact probes held by at least one pair of plates or guides which are substantially plate-shaped and parallel to each other. Said guides are provided with suitable holes and are arranged at a certain distance from each other in order to leave a free space or air gap for the movement and possible deformation of the contact probes, in particular while contacting the pads of the device under test. The pair of guides comprises a first guide indicated as upper guide, positioned closer to the testing apparatus comprising the probe head, and a second guide indicated a lower guide, positioned closer to a wafer comprising the devices under test, both guides being provided with respective guide holes within which the contact probes axially slide, usually formed by special alloys with good electric and mechanical properties.

The good connection between the contact probes of the probe head and the contact pads of the device under test is ensured by the pressure of the probe head on the device itself, the contact probes, which are movable within the guide holes formed in the upper and lower guides, undergoing, during said pressing contact, a bending inside the air gap between the two guides and a sliding inside said guide holes.

Furthermore, the bending of the contact probes in the air gap may be facilitated through a suitable configuration of the probes themselves or of the guides thereof, as schematically illustrated in FIG. 1, where, for the sake of simplicity of illustration, only one contact probe of the plurality of probes usually comprised in a probe head has been illustrated, the probe head illustrated in FIG. 1 being of the so-called “shifted plates” type.

In particular, in said FIG. 1 a probe head 10 is schematically illustrated, comprising at least one upper plate or guide (upper die) 2 and a lower plate or guide (lower die) 3, having respective upper guide holes 2A and lower guide holes 3A within which at least one contact probe 1 slides, having a probe body 1C basically extended in a longitudinal development direction according to the HH axis indicated in the figure. A plurality of contact probes 1 is usually placed inside the probe head 10 with said longitudinal development direction arranged orthogonally to the device under test and to the guides, i.e. substantially vertically along the x axis using the local reference of the figure.

The contact probe 1 has at least one end or contact tip 1A. Herein and in the following the terms “end” or “tip” indicates an end portion, which is not necessarily pointed. In particular the contact tip 1A abuts onto a contact pad 4A of a device under test 4, realizing the mechanical and electric contact between said device and a testing apparatus (not represented) which said probe head 10 is an end element of.

In some cases, the contact probes are fixedly fastened to the probe head itself at the upper guide: such probe heads are referred to as “blocked probe heads”.

Alternatively, probe heads with probes that are not fixedly fastened but held interfaced to a board of the testing apparatus are used: such probe heads are referred to as “unblocked probe heads”. Usually, an unblocked probe head also comprises a so-called “space transformer”, interposed between the probe head and the testing apparatus and able to spatially redistribute the contact pads realized thereon with respect to the contact pads on the device under test, in particular relaxing the distance constraints between the centers of the pads themselves, i.e. with a transformation of the space in terms of distances between the centers of adjacent pads.

In this case, as illustrated in FIG. 1, the contact probe 1 has a further contact tip 1B, commonly indicated as contact head, towards a plurality of contact pads 5A of said space transformer 5. The good electric contact between probes 1 and space transformer 5 is analogously ensured with respect to the contact with the device under test 4 by the pressure of the contact heads 1B of the contact probes 1 onto the contact pads 5A of the space transformer 5. More generally, contact pads whereonto contact heads of the probes abut may be formed on a board, such as a PCB interface board of the testing apparatus used for the connection with the probe head 10, the previously made considerations also applying for said board.

As already explained, the upper guide 2 and the lower guide 3 are suitably spaced apart by an air gap 6 which allows the contact probes 1 to deform during the operation of the probe head 10 and ensures the contact of contact tip 1A and contact head 1B of the contact probes 1 with the contact pads 4A of the device under test 4 and with the contact pads 5A of the space transformer 5 or board of the testing apparatus, respectively. Obviously, the upper guide holes 2A and the lower guide holes 3A should be sized so as to allow a sliding of the contact probe 1 therein during the testing operations performed by means of the probe head 10 that comprises said contact probe 1.

The correct operation of a probe head is basically linked to two parameters: the vertical movement, or overtravel, of the contact probes and the horizontal movement, or scrub, of the contact tips of said contact probes, said scrub allowing the contact tips to superficially scratch the contact pads, thus removing the possible impurities accumulated thereon, for instance in the form of a thin layer or film of oxide, and thus improving the contact performed by the probe head by means of said contact probes.

All these features should be evaluated and calibrated in the manufacturing step of a probe head, and the good electric connection between probes and device under test, in particular between contact tips of the probes and contact pads of the device under test, should always be ensured.

Equally important is to ensure that the pressing contact of the contact tips of the probes onto the contact pads of the device is not so high as to cause the probe or the pad itself to break.

This problem is particularly felt in case of the so-called short probes, i.e. probes with rod-shaped body limited in length and in particular with overall dimensions lower than 5000 μm. Probes of this type are used for instance for high-frequency applications, the reduced length of the probes limiting the connected self-inductance phenomenon, which is strongly penalizing in high-frequency applications, this term indicating applications involving signals carried by the probes with frequencies greater than 1000 MHz.

In this case, however, the reduced length of the body of the probes dramatically increases the rigidity of the probe as a whole, which implies an increase in the force exerted by the respective contact tip onto the contact pads of the device under test, which may cause said pads to break, with irreparable damage to the device under test, a situation which is obviously to be avoided. Even more dangerously, the increase in the rigidity of the contact probe due to the reduction of the length of its body increases the risk of breakage of the probes themselves, causing malfunction of the probe head as a whole and the need for its replacement or repair.

To solve these problems, it is known to make probes having one or more openings extended along the related rod-shaped bodies, able to reduce the rigidity of the probes and consequently the pressure exerted by the probes onto the contact pads, meanwhile ensuring a sufficient elasticity of the body of said probes, said openings defining a plurality of arms, substantially parallel to each other in the body of the probes.

In this case, with reference to FIGS. 2A and 2B, a contact probe 1 comprises an opening 12 or a plurality of openings 12a, 12b made in correspondence of the body 1C thereof and adapted to define a plurality of arms 11a, 11b or 11a, 11b and 11c therein. Probes of this type are described for instance in U.S. Pat. No. 7,850,460 granted on 14 Dec. 2010 to Feinmetall GmbH.

Thanks to the presence of the openings and arms in the bodies of the probes, it is immediate to verify that the probes made in this way have an increased elasticity and are therefore less subjected to breakage, while ensuring signals to be carried having a sufficiently high current value for the related applications, i.e. in particular for high-frequency applications.

Though advantageous under various aspects, this solution is not sufficient to ensure that the pressure exerted by the contact tips onto corresponding contact pads of the device under test does not cause breakages on said pads, affecting the good operation of the device once tested.

Furthermore, this known solution is not effective in relieving the pressure exerted by the probes in correspondence of the contact heads thereof, in particular in case of unblocked probes, whose contact heads equally abut onto the contact pads of a space transformer or in general of a board of a testing apparatus, running the risk of breaking said pads.

It is further well known to make at least one enlarged portion in correspondence of said contact heads 1C, able to ensure that the contact probes 1 may not slip out of the corresponding guide holes 2A, 3A made in the upper guide 2 or lower guide 3 of the probe head 10, said enlarged portion thus having greater dimensions than the rest of the contact probe 1, in particular at least one diameter greater than the diameter of the probe body 1C, the term “diameter” indicating the dimension of greatest extension of corresponding cross sections.

It is emphasized that precisely the increased dimensions of the enlarged portions in correspondence of the contact heads 1C of the contact probes 1 increase their rigidity and exacerbate the aforementioned problems relating to the impact of the probes onto the contact pads 5A of the space transformer 5, as illustrated in FIG. 1, or anyway of pads made on a connection board with the testing apparatus which the probe head 10 is the end element of.

The technical problem of the present invention is to provide a contact probe for probe heads of integrated devices having sufficient elasticity not only overall but in particular at the contact head portion thereof, so as to reduce the force exerted while abutting onto the corresponding contact pads towards the testing apparatus connected to the probe head, while ensuring the proper electric and mechanical contact of the probes on said pads, thus overcoming the limitations and drawbacks still affecting the contact probes made according to the prior art.

### DISCLOSURE OF INVENTION

The solution idea underlying the present invention is to provide contact probes with at least one opening extended along the corresponding rod-shaped bodies, said opening being also suitably extended in correspondence of at least one end portion, so that the probe body is made of at least one pair of arms separated by a first opening part and the at least one end portion is made of at least two end sections separated by a second opening part, so as to decrease the rigidity of the probes as a whole and in particular in correspondence of said at least one end portion and as a result the pressure exerted by the probes on the corresponding contact pads, while ensuring a sufficient elasticity of the body of said probes and a proper contact of the end portions thereof on corresponding contact pads of a device under test or of a board of a testing apparatus connected to a probe head housing said probes.

Based on this solution idea, the technical problem is solved by a contact probe having a first contact end portion adapted to abut onto a contact pad of a board of a testing apparatus and a second contact end portion adapted to abut onto a contact pad of a device under test, as well as a rod-shaped probe body extended between said first and second contact end portions according to a longitudinal direction, characterized in that it comprises at least one opening extending along the probe body and along at least one of said first and second contact end portions, a first opening part defining at least one pair of arms in the probe body and a second opening part defining at least one pair of end sections in the at least one of said first and second contact end portions.

More particularly, the invention comprises the following additional and optional features, taken singularly or in combination if needed.

According to an aspect of the invention, the opening may comprise the first opening part having transversal dimension greater than a transversal dimension of the second part of the opening.

According to another aspect of the invention, the opening may comprise a gradual transition between the first opening part and the second opening part, preferably according to respective circle arcs.

Furthermore, the opening may comprise the second opening part which defines at least one pair of end sections in the first contact end portion and a further opening part which defines at least one further pair of end sections in a second contact end portion.

According to another aspect of the invention, the contact probe may comprise material bridges adapted to connect distinct probe portions defined by the opening.

In particular, said material bridges may be made in the first part of the opening.

Furthermore, according to an aspect of the invention, the first contact end portion may be a contact head portion and further may comprise at least one enlarged area having transversal diameter of greater dimensions with respect to a transversal diameter of the rest of the contact head portion defining respective undercut walls for the enlarged area, said transversal diameter being a dimension according to a transversal direction that is orthogonal to the longitudinal direction.

In particular, the contact head portion outside the enlarged area may have a transversal diameter that is smaller than a transversal diameter of the probe body. More particularly, the transversal diameter of the probe body may be equal to a transversal diameter of the contact tip portion.

According to an aspect of the invention, the contact probe may also comprise a plurality of openings made along the probe body defining therein a plurality of arms separated by first opening parts, at least one of said openings being also made along the at least one contact end portion defining a pair of end sections therein.

Furthermore, the contact probe may comprise a second contact end portion which is a tapered-shaped contact tip portion. The second contact end portion may also be a contact tip portion provided with a reduced and elongated portion.

The technical problem is also solved by a probe head for testing the functionality of a device under test comprising at least one guide provided with guide holes for housing a plurality of contact probes characterized in that the contact probes are made as above indicated.

According to an aspect of the invention, each contact probe may comprise end sections in pressing contact onto a single contact pad or comprise each of the end sections in pressing contact onto a respective distinct contact pad.

Finally, according to another aspect of the invention, the guide holes of the at least one guide may house all of the arms of each contact probe or house each a distinct arm of each of said contact probes.

The characteristics and advantages of the contact probe according to the invention will become apparent from the following description of an embodiment thereof, given by way of indicative and non-limiting example, with reference to the attached drawings.

### BRIEF DESCRIPTION OF DRAWINGS

In these drawings:

FIG. 1 schematically shows a front view of a probe head made according to the prior art;

FIGS. 2A and 2B show respective front views of contact probes made according to the prior art;

FIG. 3 schematically shows a front view of a contact probe made according to the present invention;

FIGS. 4, 5A-5B, 6, 7 and 8 schematically show respective front views of alternative embodiments of the contact probe according to the present invention;

FIGS. 9-11 schematically show a front view of a probe head comprising a plurality of contact probes made according to the present invention.

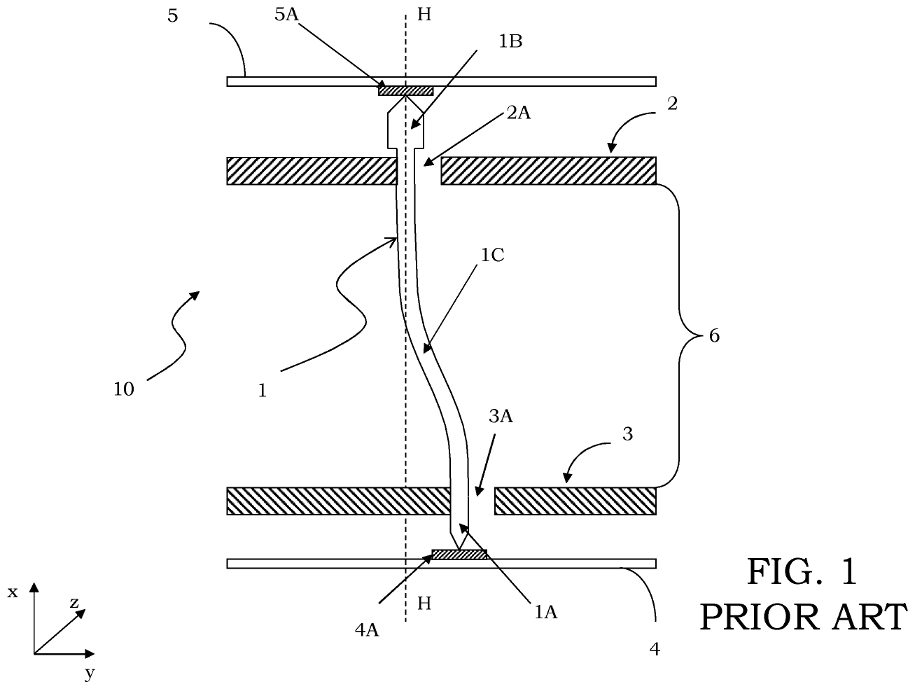

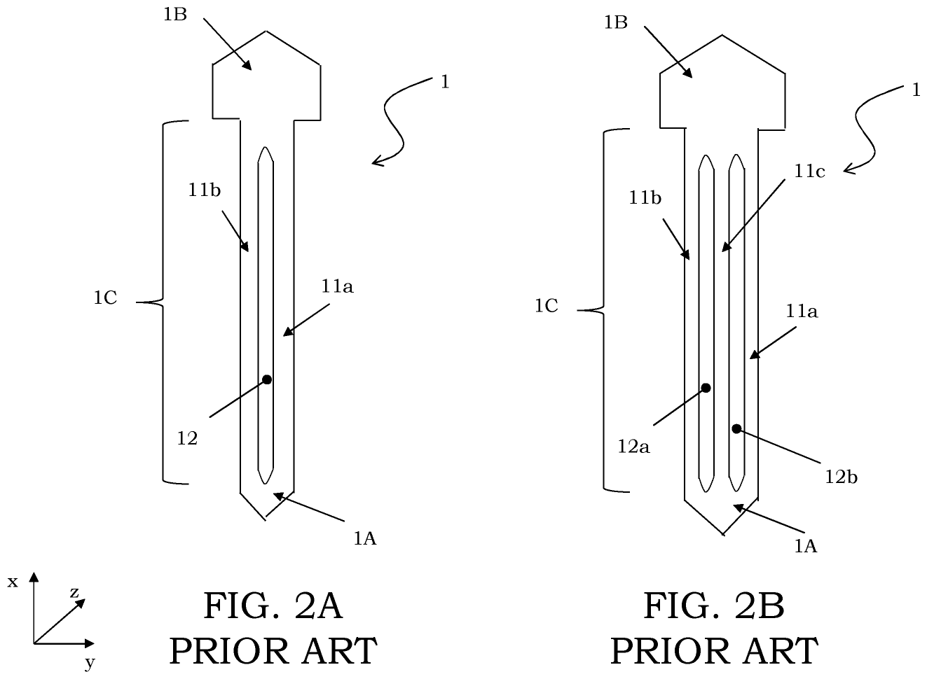

### MODES FOR CARRYING OUT THE INVENTION

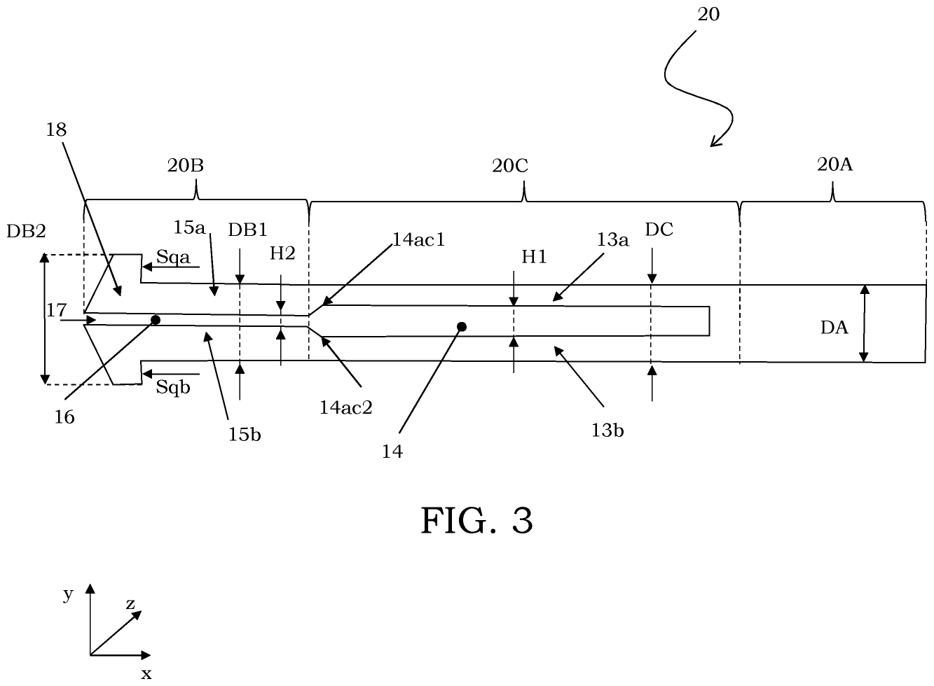

With reference to these figures, and in particular to FIG. 3, it is herein described a contact probe made according to the present invention, globally indicated with reference number 20.

It should be noted that the figures represent schematic views and are not drawn to scale, but instead they are drawn so as to enhance the important features of the invention. Furthermore, in the figures, the different pieces are shown schematically since their shape may vary according to the desired application. Finally, particular features illustrated in one figure in relation to an embodiment may also be used in one or more of the embodiments illustrated in the other figures.

The contact probe 20 comprise a first contact end portion 20A and a second contact end portion 20B, as well as a rod-shaped probe body extended between said end portions, according to a longitudinal direction, in particular the x direction of the local reference of the figure.

As seen in connection to the prior art, the first end portion has a contact end adapted to abut onto a contact pad of a device under test and is usually indicated as contact tip portion 20A and the second end portion has a contact end adapted to abut onto a contact pad of a board of a testing apparatus and is usually indicated as contact head portion 20B.

Suitably, the contact probe 20 further comprises at least one opening 17, extending along the body 20C, as well as along at least one end portion, in the example of FIG. 3 along the contact head portion 20B. In particular, the opening 17 comprises a first opening part 14 extending along the entire length of the probe body 20C, which is thus formed by at least one first and one second arm, 13a, 13b, substantially parallel to each other, separated by said first opening part 14 and a second opening part 16 extending along the entire length of the contact head portion 20B, which is thus formed by two sections, in particular two head sections 15a, 15b, preferably specular and separated by said second opening part 16.

It is emphasized how, thanks to the presence of the opening 17, the rigidity of the contact probe 20 is dramatically reduced. In particular, the creation of the arms 13a, 13b in the probe body 20C reduces the force exerted by the contact tip portion 20A on a corresponding contact pad of a device under test, not illustrated in the figure. More particularly, said force is less than a known contact probe of equal dimensions, in the absence of the arms 13a, 13b.

Moreover, the separation of the contact head portion 20B into the two head sections 15a, 15b thanks to the second opening part 16 analogously allows reducing the force exerted by said contact head portion 20B onto corresponding pads of a PCB board of a testing apparatus, being also not illustrated.

It is also immediate to verify that such a contact head portion 20B allows ensuring a proper contact with the board of the testing apparatus, in particular a double contact that occurs thanks to the pressure of the two head sections 15a, 15b on a corresponding contact pad of said board.

It is emphasized how the double contact made by the head sections 15b of the contact head portion 20B in particular ensures a proper contact with the board of the testing apparatus in case of incorrect alignment of said board and thus a possible inclination of the corresponding contact pads, as well as in the case of an inclination of the contact probe 20 once mounted in a probe head or further to a deformation thereof when the probe head abuts onto the corresponding device under test, i.e. during the so-called overtravel.

Preferably, the transversal dimension H1, i.e. along the y axis of the local reference of the figure, orthogonal to the longitudinal direction according to the x axis, of the first opening part 14 extended along the probe body 20C is greater than the transversal dimension H2 of the second opening part 16 extended along the contact head portion 20B.

It is emphasized that the change of transversal dimension between the first opening part 14 and the second opening part 16 could result in a step configuration, in particular a 90° step configuration; in the preferred embodiment of FIG. 3, the transition between the first opening part 14 and the second opening part 16 is instead gradual, preferably according to respective circle arcs 14ac1, 14ac2, so as to reduce the possibility of creating critical points for the formation of cracks or breaks in the probe itself, the use of a continuous opening between the probe body 20C and the contact head portion 20B already reducing the possibility of said undesired cracks or breaks along the entire probe body and the end portion affected by said opening 14.

In said preferred embodiment illustrated in FIG. 3, the contact head portion 20B comprises at least one enlarged area 18, i.e. having a transversal diameter DB2 of greater dimensions than a transversal diameter DB1 of the rest of the contact head portion 20B; in particular, said enlarged area 18 is the area of the contact head portion 20B ending with the head end that abuts onto the pads of the board of the testing apparatus and is tapered so as to realize an end of reduced diameter. In this way, respective undercut walls Sqa, Sqb are defined for the head sections 15a, 15b adapted to contact a guide housing the contact probe in correspondence of a guide hole thereof. In particular, said guide hole will need to be sized so as to slidingly house the contact probe 20 meanwhile preventing its passage at the enlarged area 18, as explained hereinafter.

The contact probe 20 comprising the enlarged area 18 has an improved holding inside a probe head, the abutment of the undercut walls Sqa, Sqb onto the guide acting so as to prevent a movement of the contact probe 20 downwards, i.e. towards the device under test, in particular when the probe head is removed from the wafer comprising the device under test and the probes are in this way free to move, said movement being favoured in case of an even temporary coupling of the contact tip portions 20A thereof onto the contact pads of the device under test.

The contact probe 20 illustrated in FIG. 3 comprises head sections 15b that are equal and specular to each other, but it is obviously possible to make said sections differently, for instance with an enlarged portion just at one of the two head sections, an undercut wall anyway resulting for abutting onto the corresponding guide, so as to ensure the correct holding of the contact probe 20 inside the probe head, even when it is not contacting the wafer of devices under test and in particular when moved from said wafer a testing operation has been performed.

In the illustrated embodiment of FIG. 3, the contact probe 20 further has respective transversal diameters DA and DC of its contact tip portion 20A and of probe body 20C that are equal to each other and to the transversal diameter DB1 of the contact head portion 20B where the enlarged area 18 is not present.

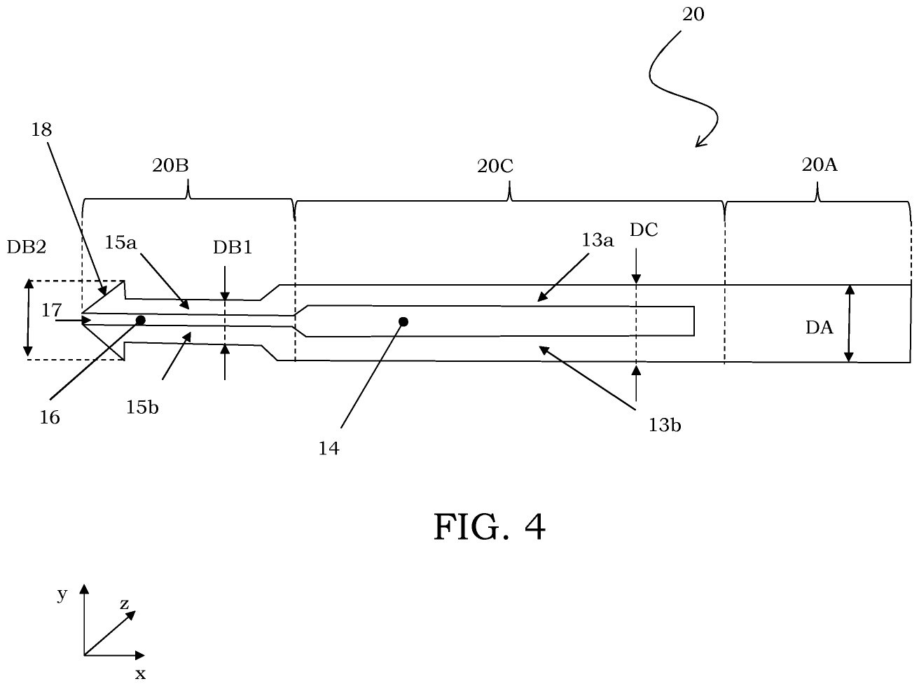

According to an alternative embodiment illustrated in FIG. 4, the transversal diameter DB1 is instead smaller than the transversal diameter DC of the probe body 20C; in the example of the figure, said transversal diameter DC of the probe body 20C is anyway equal to the transversal diameter DA of its contact tip portion 20A. In this way, suitably according to this alternative embodiment, the enlarged area 18 may have a transversal diameter DB2 that is equal to the transversal diameters DA and DC of its contact tip portion 20A and of the probe body while realizing undercut walls Sqa, Sqb able to ensure the proper holding of the contact probe 20 in the probe head.

Therefore the contact probe 20 according to the alternative embodiment of FIG. 4 has a maximum transversal size of its contact head portion 20B, in correspondence of the enlarged area 18, that is equal to the transversal size of the rest of the contact probe 20, in correspondence of the probe body 20C and of the contact tip portion 20A.

In this way it is possible, in a probe head comprising a plurality of contact probes 20 made according to the alternative embodiment of FIG. 4, to get the probes close to each other at the contact head portions i.e. to use the interface boards with the testing apparatus with a smaller pitch, with respect to the embodiment illustrated in FIG. 3, in particular a pitch equal to that of the device under test.

In this case, the guide housing said contact probes 20 in correspondence of the contact head portions 20B thereof is made with guide holes of dimensions, in particular a transversal diameter, suitable for housing said contact head portions 20B, while ensuring the abutment of the undercut walls Sqa, Sqb. In other words, the following relationship is verified:

DB2>DFG>DB1
being:
DFG the transversal diameter of the guide holes;
DB2 the transversal diameter of the enlarged area 18; and
DB1 the transversal diameter of the rest of the contact head portion 20B.

Also in this case, the term “transversal diameter” indicates a maximum size dimension of a section taken on a transversal plane that is orthogonal to the longitudinal development axis corresponding to the x direction of the local reference of the figures.

It is emphasized that in this case the second opening part 16 ensures that the contact head portion 20B has a so-called “spring effect” which allows the assembly under pressure thereof inside guide holes of smaller dimensions than the transversal diameter DB2 of the enlarged area 18, thanks to the approach of the head sections 15a, 15b when said enlarged area 18 is pushed into the guide hole until it passes through it, abutting with the undercut walls against the corresponding guide, positioned below the contact head portion 20B and in particular below the enlarged area 18.

It is anyway possible to make the enlarged area 18 with a transversal diameter DB2 still slightly greater than the transversal diameter of the probe body 20C, so as to ensure the abutment of the undercut walls Sqa, Sqb onto the corresponding guide even in case of a relevant clearance of the guide holes thereof, while increasing the size of the contact probe 20 only to a limited extent as a whole thanks to the smaller diameter in correspondence of the contact head portion 20B.

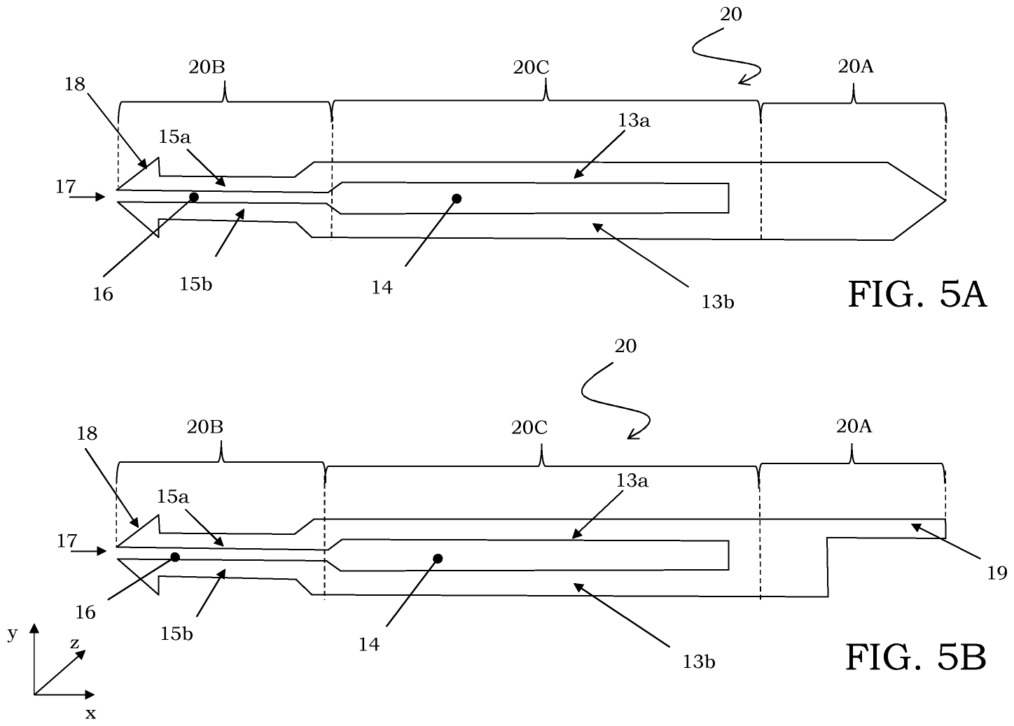

It is also possible to consider alternative embodiments of the contact probe 20 which comprise contact tip portions 20A that are tapered-shaped or provided with reduced and elongated portions 19, as illustrated in FIGS. 5A and 5B, starting from the embodiment of FIG. 4.

Obviously, it is possible to also make the contact probe 20 of FIG. 3 so as to comprise contact tip portions 20A that are tapered-shaped or provided with reduced and elongated portions 19.

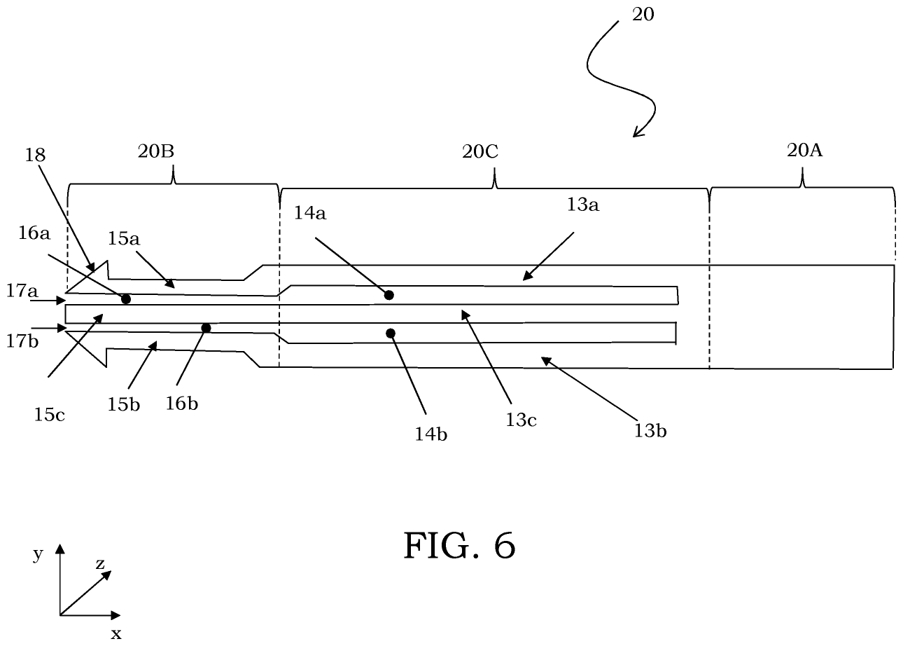

A further alternative embodiment of the contact probe 20 is schematically illustrated in FIG. 6. In particular, in this case the contact probe 20 comprises a plurality of openings 17a, 17b longitudinally made along the probe body 20C, at least one of said openings, alternatively all of the openings, being also extended in the contact head portion 20B.

In this way, the contact probe 20 comprises a probe body 20C made by a plurality of arms 13a, 13b, 13c separated by first opening parts 14a, 14b of the openings 17a, 17b and a contact head portion 20B made by at least one pair of head sections, possibly by a plurality of head sections 15b, 15c, separated by at least one second opening part of at least one opening 17a or 17b, possibly respective second opening parts 16a, 16b of all of the openings 17a, 17b.

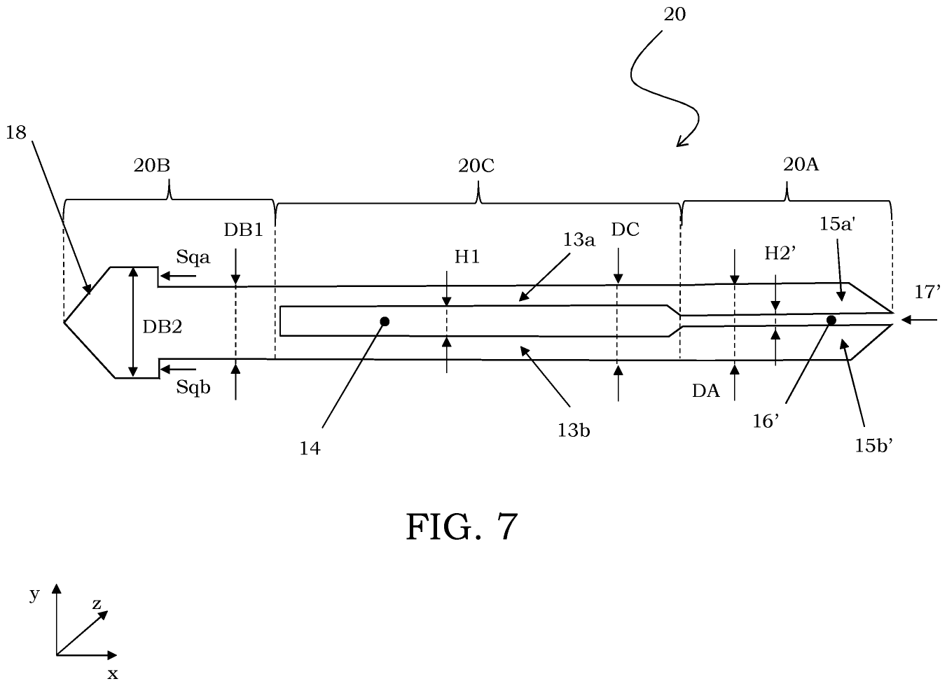

According to an alternative embodiment illustrated in FIG. 7, the contact probe 20 comprises at least one opening 17′, extending along the body 20C as well as along at least one end portion, in particular along the contact tip portion 20A. In this case, the opening 17′ comprises a first opening part 14 extending along the entire length of the probe body 20C, which is thus formed by at least one first and one second arm, 13a, 13b, substantially parallel to each other, separated by said first opening part 14 and a second opening part 16′ extending along the entire length of the contact tip portion 20A, which is thus formed by two end sections, in particular two tip sections 15a′, 15b′, preferably specular and separated by said second opening part 16′.

Still according to said alternative embodiment, the presence of the opening 17′ allows drastically reducing the rigidity of the contact probe on the one hand, thanks to the creation of the arms 13a, 13b in the probe body 20C and, on the other hand, thanks to the separation of the contact tip portion 20A into the two tip sections 15a′, 15b′ which contribute reducing the force exerted by the contact tip portion 20A on a corresponding contact pad of a device under test, not illustrated in the figure, said force is less than a known contact probe of equal dimensions, in the absence of the arms 13a, 13b and of the partition of the contact tip portion 20A.

The partition of the contact tip portion 20A into the two tip sections 15b′ also ensures a proper contact with the contact pads of the device under test, by realizing a double contact which occurs thanks to the pressure of the two tip sections 15a′, 15b′ separately on said contact pads, even in case of incorrect alignment of the wafer that comprises the device under test or in case of inclination of the contact probe once mounted in the probe head or even further to its deformation when the probe head abuts onto the corresponding device under test, i.e. during the so-called overtravel.

Preferably, the transversal dimension H1 along the y axis of the local reference of the figure, orthogonal to the longitudinal direction according to the x axis, of the first opening part 14 extended along the probe body is greater than the transversal dimension H2′ of the second opening part 16′ extended along the contact tip portion 20A, the transition between the first opening part 14 and the second opening part 16′ being preferably gradual, according to respective circle arcs, so as to reduce the possibility of creating critical points for the formation of cracks or breaks in the probe itself, as seen previously.

Moreover, in the embodiment illustrated in FIG. 7, the contact head portion 20B comprises at least one enlarged area 18, i.e. having a transversal diameter DB2 of greater dimensions than a transversal diameter DB1 of the rest of the contact head portion 20B; in particular, said enlarged area 18 is the area of the contact head portion 20B ending with the head end abutting onto the pads of the board of the testing apparatus and is tapered so as to form an end of reduced diameter. In this way, respective undercut walls Sqa, Sqb for the enlarged area 18 are defined, which are adapted to abut onto a guide housing the contact probe 20 at a guide hole thereof, sized so as to slidingly house said probe and meanwhile to prevent the passage thereof in correspondence of the enlarged area 18, so as to improve the holding of the probe inside a probe head.

The contact probe 20 illustrated in FIG. 7 comprises tip sections 15b′ that are equal and specular to each other, but it is obviously to make said sections differently.

As seen previously, it is possible to make the contact probe 20 with a transversal diameter DB1 of the contact head portion 20B where the enlarged area 18 is not present, which diameter is smaller than the transversal diameter DC of the probe body 20C, thus reducing the overall size of the contact head portion 20B in the y transversal direction.

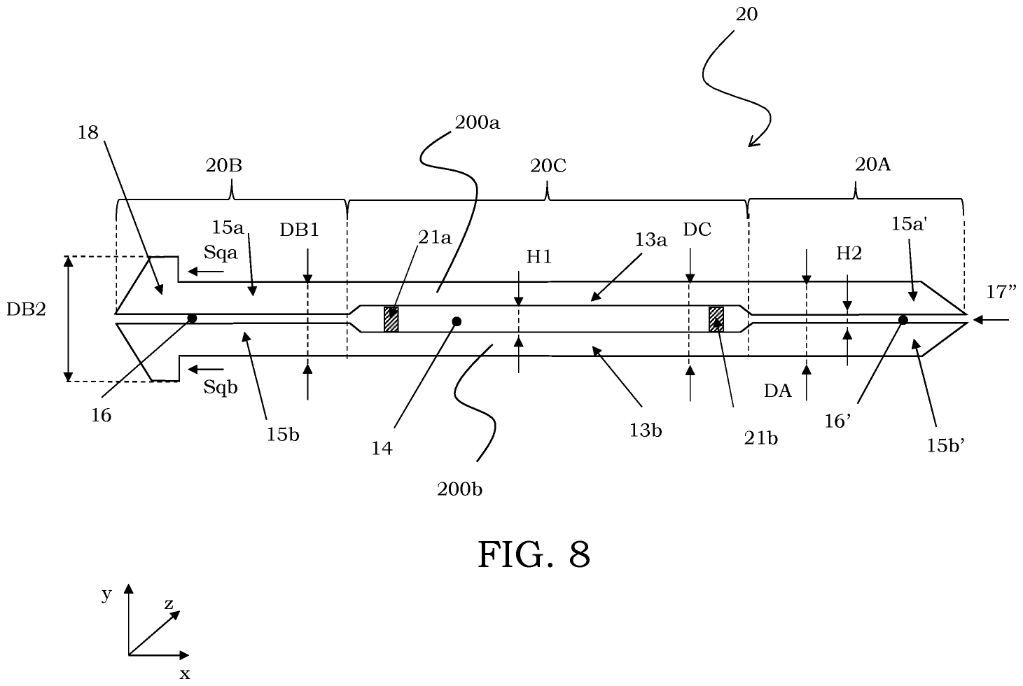

According to a further alternative embodiment schematically illustrated in FIG. 8, the contact probe 20 comprises at least one opening 17″, extending along the body 20C as well as along both end portions, i.e. along the contact tip portion 20A and along the contact head portion 20B. In this case, the opening 17″ comprises a first opening part 14 extending along the entire length of the probe body 20C, which is thus formed by at least one first arm and one second arm, 13a, 13b, substantially parallel to each other, separated by said first opening part 14, a second opening part 16 extending along the entire length of the contact head portion 20B, which is thus formed by two end sections, in particular two head sections 15a, 15b, preferably specular and separated by said second opening part 16, and a further opening part 16′ extending along the entire length of the contact tip portion 20A, which is thus formed by two end sections, in particular two tip sections 15a′, 15b′, preferably specular and separated by said further opening part 16′.

In this way, the contact probe 20 is divided by the opening 17″ into two probe portions, 200a and 200b, preferably specular and separated by said opening 17″.

Suitably, the contact probe 20 also comprises at least one material bridge adapted to connect the two probe portions, 200a and 200b, with each other. In the embodiment illustrated in FIG. 8, the contact probe comprises a first material bridge 21a and a second material bridge 21b positioned inside the first opening part 14, preferably at opposite ends thereof, i.e. close to the second opening part 16 and to the further opening part 16′, respectively.

In this case, it is emphasized that both the end portions, being divided into two distinct sections, are able to make a double contact with corresponding pads of the device under test and of the board of the testing apparatus, respectively.

As previously, the contact head portion 20B comprises at least one enlarged area 18, i.e. having a transversal diameter DB2 of greater dimensions than a transversal diameter DB1 of the rest of the contact head portion 20B, so as to define respective undercut walls Sqa, Sqb adapted to contact a guide that houses the contact probe 20.

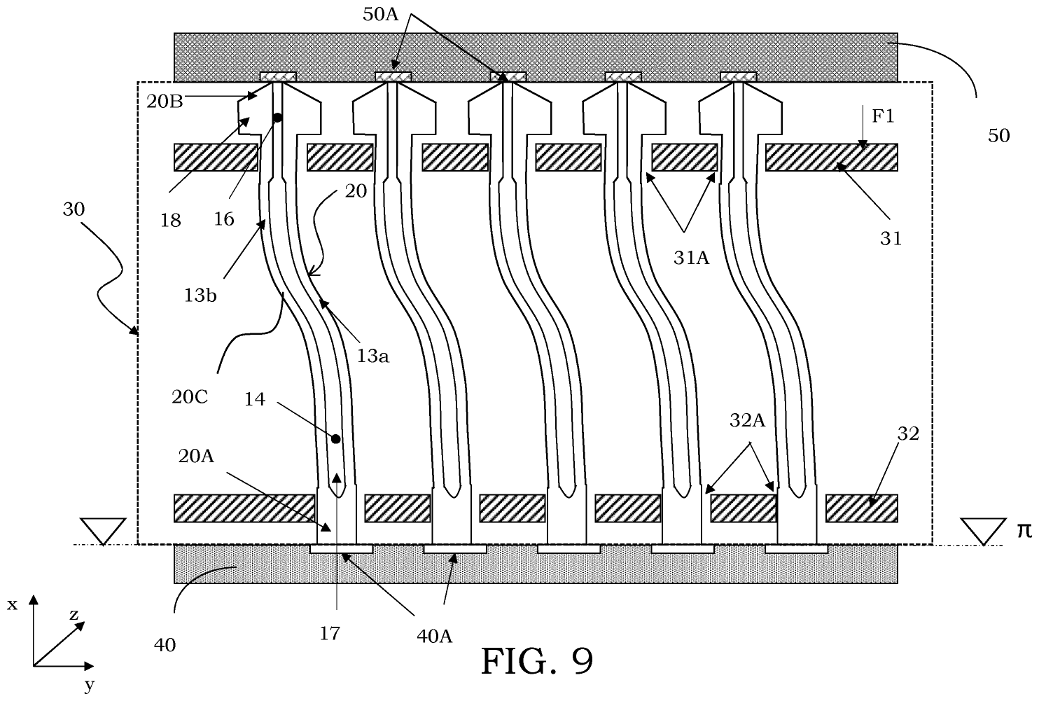

A probe head comprising a plurality of contact probes 20 made according to the present invention is schematically illustrated in FIG. 9, globally indicated with reference number 30. In particular, in the example of FIG. 9, the contact probes 20 are made according to the embodiment of FIG. 3, just by way of example.

The probe head 30 comprises an upper guide 31 and a lower guide 32, having respective upper guide holes 31A and lower guide holes 32A within which a plurality of contact probes 20 slide, in the example of figure in the number of five. The contact probes 20 have their probe body 20 basically extended in a longitudinal development direction x of the local reference of the figure, orthogonal to a plane n corresponding to the plane of a wafer comprising the device under test 40.

Each contact probe 20 has a contact tip portion 20A having a contact end adapted to abut onto a contact pad 40A of the device under test 40 and a contact head portion 20B having a contact end adapted to abut onto a contact pad 50A of a board of the testing apparatus, such as a space transformer 50.

Suitably, each contact probe 20 comprises an opening 17 having a first part 14 arranged along the probe body 20C and defining therein a pair of arms 13a, 13b and a second part 16 arranged along the contact head portion 20B and defining therein a pair of head sections, 15a, 15b.

In this way, as previously explained, during the operation of the probe head 30 and the pressing contact of the contact probes 20 thereof onto the device under test 40 and onto the space transformer 50, respectively, the proper operation of each contact probe 20 is ensured thanks to the presence of the arms 13a, 13b in the probe body 20C, which attribute to the contact probe 20 and in particular to the contact tip portion 20A sufficient elasticity to ensure a pressing contact onto the contact pads 40A of the device under test 40 without the risk of breaking the pads or the probe, as well as thanks to the presence of the head sections 15a, 15b that ensure a similar elasticity also for the pressing contact of the contact head portion 20B with the contact pads 50A of the space transformer 50, said head sections 15a, 15b further realizing a double contact on said pads.

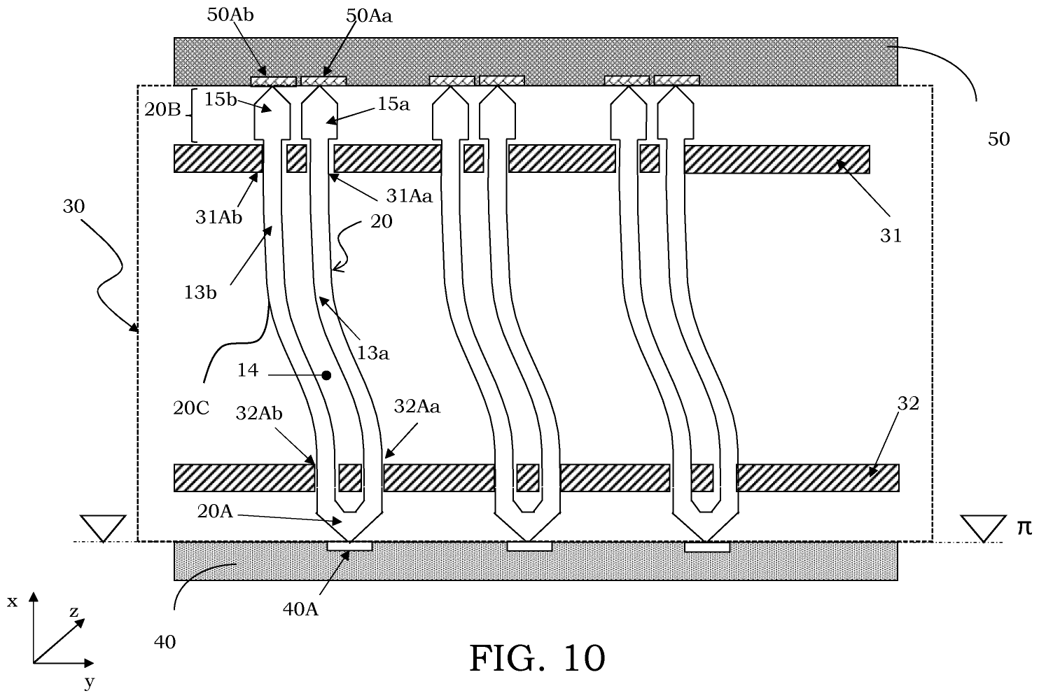

According to an alternative embodiment schematically illustrated in FIG. 10, the probe head 30 comprises a plurality of contact probes 20 (in the figure in the number of three), each contact probe 20 having head sections 15a and 15b in pressing contact on respective distinct contact pads, 50Aa and 50Ab of the space transformer 50.

Furthermore, the upper guide 31 and the lower guide 32 may comprise, as illustrated in FIG. 10, a plurality of respective guide holes, 31Aa, 31Ab and 32Aa, 32Ab, each one adapted to house an arm 13a, 13b of a contact probe 20, in the example a pair of guide holes house a pair of arms.

It is for instance possible to use said alternative embodiment of the probe head 30 in case of the so-called force and sense probes which abut onto a single contact pad 40A of the device under test 40. Suitably according to the present invention, in these conditions, the parasitic resistance of the contact probe 20 is almost entirely compensated, only excluding the contact tip portion 20A.

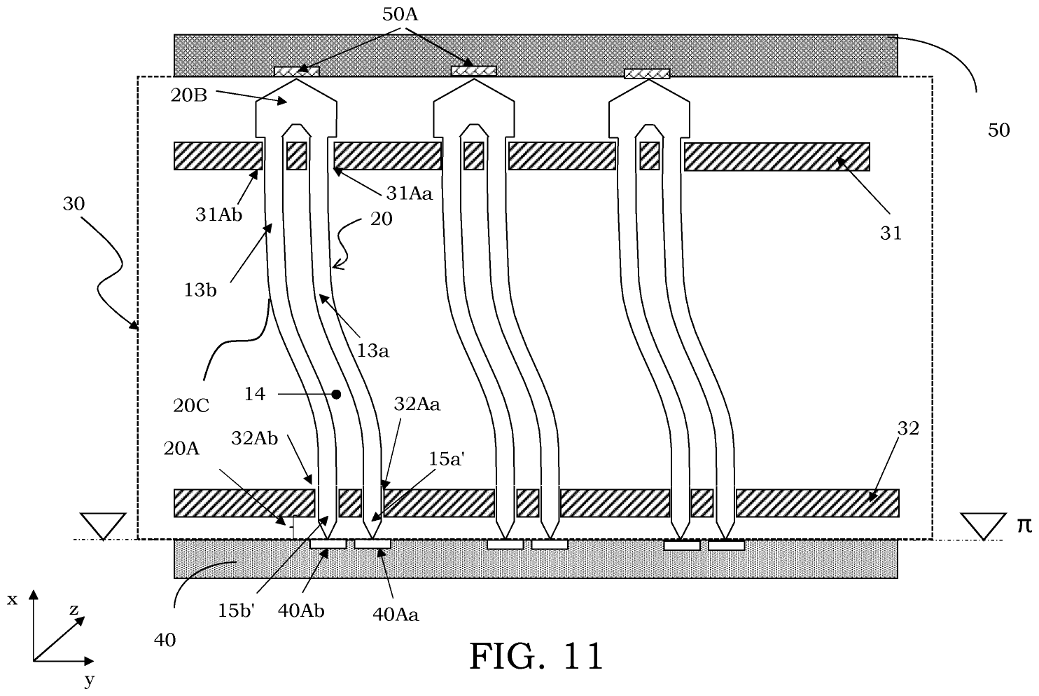

It is also possible, as schematically illustrated in FIG. 11, to make the probe head 30 so as to comprise a plurality of contact probes 20 having at least a pair of tip sections, 15a′, 15b′ in correspondence of each arm 13a, 13b, each of said tip sections 15a′ and 15b′ abutting onto a respective contact pad 40Aa, 40Ab of the device under test 40, whereas the contact head portion 20B abuts onto a single contact pad 50A of the space transformer 50.

Also on this case, the upper guide 31 and the lower guide 32 may comprise a plurality of respective guide holes, 31Aa, 31Ab and 32Aa, 32Ab, each one adapted to house an arm 13a, 13b of a contact probe 20, in the example in the number of two.

In this case it is possible to short-circuit two distinct contact pads 40Ab of the device under test 40 and to connect them to a single contact pad 50A of the space transformer 50 only using one contact probe comprised in the probe head 30, which in the example of FIG. 11, only by way of example, comprises three contact probes.

Obviously, using contact probes provided with a number of arms greater than two, it is possible to make a probe head whose probes are in pressing contact in correspondence of the head and/or tip sections thereof with a number of contact pads of the space transformer and/or of the device under test greater than two.

In conclusion, the contact probe provided with at least one opening extending along its probe body and with at least one contact end portion thereof has an improved elasticity during the contact of said contact end portion on corresponding contact pads, thus reducing the rigidity of the probe as a whole and drastically reducing the possibilities of breakage thereof, thanks to the presence of the plurality of arms in its probe body and meanwhile ensuring a proper reduction in the pressure exerted by the at least one contact end portion, thanks to the presence of the plurality of end sections formed in said portion by a corresponding part of the opening.

Suitably, the presence of a plurality of end sections, in particular head sections and/or tip sections, is also able to make an at least double contact, possibly multiple, which ensures the proper connection of such a contact probe with the board of the testing apparatus and with the device under test, also in case of an incorrect alignment thereof and thus of a possible inclination of the corresponding contact pads, as well as in case of an inclination of the contact probe once mounted in a probe head or further to the deformation thereof when the probe head abuts onto the corresponding device under test and onto the board of the testing apparatus.

The contact probes made according to the present invention have performance suitable to their use in high-frequency applications, in particular allowing the necessary reduction in the longitudinal dimensions of the bodies of the probes without the risk of damaging the pads or breaking the probes.

Furthermore, since the opening, which said probes are provided with, is formed continuously therein, in particular along their probe bodies and along their contact end portions, the suggested solution does not introduce discontinuity or critical points into the probes, which could result in the formation of cracks, at least always resulting in the breakage of the probes themselves.

The combined use of said opening and of a reduced diameter of the contact head portion further allows keeping the maximum size of the probes unchanged and thus reducing, compared with the known solutions, the pitch of the board of the testing apparatus connected to a probe head comprising said probes while ensuring the correct holding of the probes in the probe head thanks to the presence of the enlarged area made in the contact head portion.

The presence of said enlarged area in particular ensures the abutment of the undercut walls thereof onto a corresponding guide acting so as to prevent a movement of the contact probes towards the device under test, for instance at the end of the testing operations, when the probe head is removed from the wafer comprising the device under test, also in case of an undesired gluing of the contact tip ends with the pads of the device under test.

It is also possible to make the probe head so that the head and/or tip sections of the probes thereof are in pressing contact on distinct contact pads of the device under test and/or of the space transformer, so as to short-circuit said pads with each other.

Obviously a person skilled in the art, in order to satisfy contingent and specific requirements, may make to the contact probe above described numerous modifications and variations, all included in the scope of protection of the invention as defined by the following claims.

In particular, it is possible to consider any number of longitudinal openings so as to form any number of arms in the probe body, one or more of these openings may also prosecute in the contact head portion and/or in the contact tip portion, along the entire extension thereof or just along a part thereof; moreover it is possible to make the probe with arms and/or openings of different dimensions both in the transversal direction and in the longitudinal direction, even if not illustrated in the figures.

It is also possible to make probes of different type, such as vertical probes or buckling beam, in particular of the blocked or unblocked type, with free body and possibly pre-deformed.

Finally, it is possible to provide the contact probe of the present invention with further features, such as stoppers protruding from the probe body, in addition to other geometric configurations of the tip portions and of the contact head.

1. A contact probe having:
a first contact end portion adapted to abut onto a contact pad of a board of a testing apparatus,
a second contact end portion adapted to abut onto a contact pad of a device under test, and
a rod-shaped probe body extended between the first and second contact end portions according to a longitudinal direction, the contact probe further comprising:
an opening that extends along the probe body and along at least one of the first and second contact end portions,
a first opening part defining a at least one pair of arms in the probe body, and
a second opening part defining a pair of end sections in the first and second contact end portions.

2. The contact probe of claim 1, wherein the one opening comprises the first opening part having transversal dimension greater than a transversal dimension of the second opening part.

3. The contact probe of claim 2, wherein the opening comprises a gradual transition between the first opening part and the second opening part.

4. The contact probe of claim 1, wherein the opening comprises the second opening part which defines a at least one pair of end sections in a first contact end portion and a further opening part which defines a further pair of end sections in a second contact end portion.

5. The contact probe of claim 4, further comprising material bridges adapted to connect distinct probe portions defined by the opening.

6. The contact probe of claim 5, wherein the material bridges are in correspondence of the first part of the opening.

7. The contact probe of claim 1, wherein the first contact end portion is a contact head portion and further comprises an enlarged area having a transversal diameter of greater dimensions with respect to a transversal diameter of the rest of the contact head portion defining respective undercut walls for the enlarged area, the transversal diameter being a dimension according to a transversal direction that is orthogonal to the longitudinal direction.

8. The contact probe of claim 7, wherein the contact head portion outside the enlarged area has a transversal diameter that is smaller than a transversal diameter of the probe body.

9. The contact probe of claim 8, wherein the transversal diameter of the probe body is equal to a transversal diameter of the contact tip portion.

10. The contact probe of claim 1, further comprising a plurality of openings made along the probe body defining a plurality of arms therein, separated by first opening parts, wherein one of the openings being also is made along the at least one contact end portion defining a pair of end sections therein.

11. The contact probe of claim 1, further comprising a second contact end portion which is a tapered-shaped contact tip portion.

12. The contact probe claim 1, further comprising a second contact end portion that is a contact tip portion provided with a reduced and elongated portion.

13. A probe head for the functionality testing of a device under test comprising a guide provided with guide holes for housing a plurality of contact probes wherein each of the contact probes has:
a first contact end portion adapted to abut onto a contact pad of a board of a testing apparatus;
a second contact end portion adapted to abut onto a contact pad of a device under test; and
a rod-shaped probe body extended between the first and second contact end portions according to a longitudinal direction; and
each contact probe further including:
an opening that extends along the probe body and along at least one of the first and second contact end portions,
a first opening part defining a pair of arms in the probe body, and
a second opening part defining a pair of end sections in the first and second contact end portions.

14. The probe head of claim 13, wherein each contact probe comprises the end sections in pressing contact onto a single contact pad.

15. The probe head of claim 13, wherein each contact probe comprises each of the end sections in pressing contact onto a respective distinct contact pad.

16. The probe head of claim 13, wherein the guide holes of the at least one guide house all of the arms of the contact probes.

17. The probe head of claim 13, wherein the guide holes of aid the guide house a distinct arm of the contact probes.

18. The contact probe of claim 3, wherein the gradual transition is according to a circle arc.
